(19) United States
(12) Patent Application Publication
(10) Pub. No.: US 2026/0037705 A1
(43) Pub. Date: Feb. 5, 2026

(54) GENERATING HARDWARE DESCRIPTION LANGUAGE SLICES TO PROVIDE CONTEXT FOR VIOLATIONS

(71) Applicant: Synopsys, Inc., Sunnyvale, CA (US)

(72) Inventors: Thanuja Madusanka, Colombo (LK); Himanshu Kathuria, Sunnyvale, CA (US); Mohan Mangal, Sunnyvale, CA (US); Jaskaran Singh Ajimal, San Jose, CA (US); Rohit Kumar Ohlayan, Noida (IN); Paras Mal Jain, Sunnyvale, CA (US)

(73) Assignee: Synopsys, Inc., Sunnyvale, CA (US)

(21) Appl. No.: 18/791,702

(22) Filed: Aug. 1, 2024

(51) Int. Cl. G06F 30/323; G06F 8/30

(52) U.S. Cl. CPC G06F 30/323; G06F 8/311

(57) ABSTRACT

Analysis may be performed on hardware description language (HDL) code to identify a violation, where the HDL code may describe an IC design, and where the violation may specify a line in the HDL code. The HDL code may be parsed to obtain a digital representation of the IC design. Connectivity information and semantic information of objects in the digital representation may be determined. A first object in the digital representation may be determined which corresponds to the line in the HDL code. The connectivity information and the semantic information may be used to identify a set of objects in the digital representation which are related to the first object. A set of lines in the HDL code may be selected which correspond to the set of objects in the digital representation.

### TECHNICAL FIELD

The present disclosure generally relates to electronic design automation (EDA) systems. More specifically, the present disclosure relates to generating hardware description language (HDL) slices to provide context for violations.

### BACKGROUND

EDA applications may be used to design and verify an integrated circuit (IC). It may be important to improve the quality of results (QoR) and performance of EDA applications.

### BRIEF DESCRIPTION OF THE FIGURES

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates a system for using a large language model (LLM) to fix static violations in HDL code in accordance with some embodiments described herein.

FIG. 2 illustrates a process for generating an HDL slice in accordance with some embodiments described herein.

FIGS. 3A-6 illustrate HDL code in accordance with some embodiments described herein.

FIG. 7 illustrates connectivity information in an IC design in accordance with some embodiments described herein.

FIG. 8 illustrates semantic information in an IC design in accordance with some embodiments described herein.

FIGS. 9-10 illustrates identifying related HDL constructs and obtaining instance constructs in the parent module in accordance with some embodiments described herein.

FIGS. 11A-11B illustrate generating an HDL slice based on identifying lines of code corresponding to a set of objects in accordance with some embodiments described herein.

FIGS. 12A-12B illustrate an HDL slice in accordance with some embodiments described herein.

FIG. 13 illustrates parameters to adjust the HDL slice generation process in accordance with some embodiments described herein.

FIG. 14 illustrates a process for generating an HDL slice in accordance with some embodiments described herein.

FIG. 15 illustrates an example set of processes used during the design, verification, and fabrication of an article of manufacture such as an integrated circuit to transform and verify design data and instructions that represent the integrated circuit.

FIG. 16 illustrates an example machine of a computer system within which a set of instructions, for causing the machine to perform any one or more of the methodologies discussed herein, may be executed.

### DETAILED DESCRIPTION

Aspects of the present disclosure relate to generating HDL slices to provide context for violations. In this disclosure, an LLM may refer to a neural network which can learn context and meaning by tracking relationships in sequential data (such neural networks may also be referred to as transformer networks). An LLM may be implemented as a set of instructions which are executed on a processing device.

An LLM may use positional encoding and self-attention. Positional encoding may refer to embedding position information with the input data. For example, each word in a sentence may be associated with a position of the word in the sentence. The position of the word may be embedded with the word so that, during training, the LLM can learn to treat the same word in different positions differently. Self-attention may refer to a process which assigns an attention weight to a particular piece of input data, where the attention weight may represent a relationship of that piece of input data with other pieces of input data. The attention weights may be learnt by the LLM during training.

The term “tokenization” may refer to converting data into a sequence of tokens, where each token may represent a portion of the data and may be the basic processing unit of the LLM. For example, a token may correspond to a word in a natural language or a keyword in a programming language. The term “inferencing” may refer to a process for using a trained LLM to generate a response based on a prompt. Specifically, the prompt may be tokenized into a sequence of input tokens, and the sequence of input tokens may be provided to the LLM as input to generate a sequence of output tokens. The sequence of output tokens may be used to generate a response (e.g., by replacing each output token with a corresponding word). The term “interaction” may refer to a single prompt-response pair in an LLM.

The computational resources (e.g., processing time and memory) which are used for training and inferencing may depend on the number of tokens in the prompt and/or response. Specifically, increasing the number of tokens may increase the computational resources which are used during training and/or inferencing. Thus, an LLM may limit the number of tokens which may be used in the LLM.

An LLM may be used to fix problems (e.g., bugs or violations) in a piece of code. For example, an LLM may be used to fix problems in hardware description language (HDL) code. It may not be possible and/or desirable to provide the entire code base as input to the LLM. Specifically, providing the entire code base as input to the LLM may violate the token limit of the LLM. Moreover, providing the entire code base as input to the LLM may confuse the LLM and may not enable the LLM to generate a useful and/or accurate response.

Some embodiments described herein may select a set of lines of HDL code (which may be referred to as an “HDL slice”) based on a static violation. The HDL slice may be provided as input to an LLM to generate a fix for the static violation. The HDL slice may be less than or equal to the token size of the LLM. Moreover, the HDL slice may include relevant HDL code lines across multiple files which may improve the QoR of the response (e.g., by increasing the probability that the response generated by the LLM correctly fixes the static violation).

Technical advantages of embodiments described herein include, but are not limited to, (1) enabling an LLM to be used for fixing a static violation by creating a prompt (e.g., the HDL slice) which is smaller than the token limit of the LLM, (2) increasing the performance of an LLM for fixing static violations by reducing the size of the prompt which is provided to the LLM, (3) decreasing an amount of memory used by an LLM for fixing static violations by reducing the size of the prompt which is provided to the LLM, and (4) increasing the usefulness and/or accuracy and/or QoR of a response generated by a processing device implementing an LLM by selecting lines of HDL code (e.g., the HDL slice) which are relevant for fixing static violations.

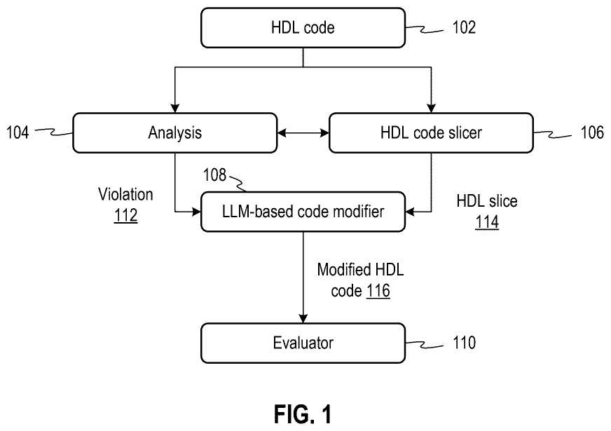

FIG. 1 illustrates a system for using an LLM to fix static violations in HDL code in accordance with some embodiments described herein.

HDL code 102 may describe an IC design. Analysis 104 may be performed on HDL code 102 to determine a set of violations. Analysis 104 may refer to techniques for analyzing HDL code to identify problems without simulating the IC design represented by the HDL code. The term “violation” may generally refer to a problem or deficiency in the IC design which is desired to be solved or fixed. Violations determined by analysis 104 may include, but are not limited to, design rule violations, structural rule violations, electrical rule violations, coding style violations, security violations (e.g., one or more lines of HDL code which allow sensitive signals in the IC design to be detected), and performance violations (e.g., one or more lines of HDL code which decrease simulation efficiency).

HDL code slicer 106 may generate HDL slice 114 based on HDL code 102 and a violation identified during analysis 104. A violation determined by analysis 104 and a corresponding HDL slice generated by HDL code slicer 106 may be provided to LLM-based code modifier 108. For example, violation 112 and the corresponding HDL slice 114 may be provided as part of a prompt to LLM-based code modifier 108.

A response generated by LLM-based code modifier 108 may be evaluated by evaluator 110. For example, the response generated by LLM-based code modifier 108 may be a modification to the HDL slice. The modification to the HDL slice may be applied to HDL code 102 to obtain modified HDL code 116. In some embodiments described herein, evaluator 110 may perform static analysis on modified HDL code 116 to determine if the static violation 112 was fixed and no new static violations were created.

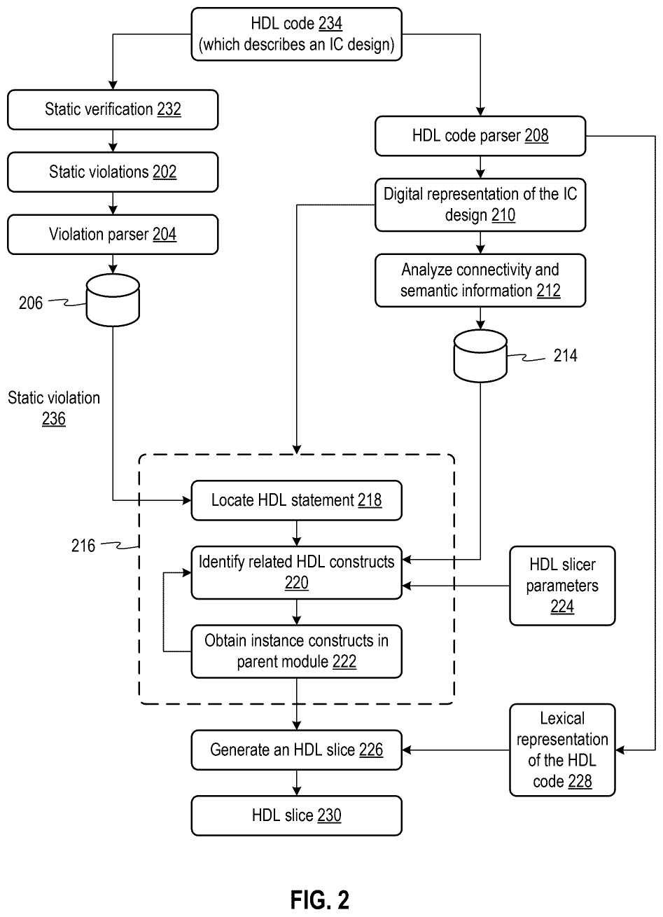

FIG. 2 illustrates a process for generating an HDL slice in accordance with some embodiments described herein.

HDL code 234 may describe an IC design. Static verification 232 (e.g., using a static analysis tool, which may be implemented using a set of instructions which are executed on a processing device) may be performed on HDL code 234 to identify static violations 202.

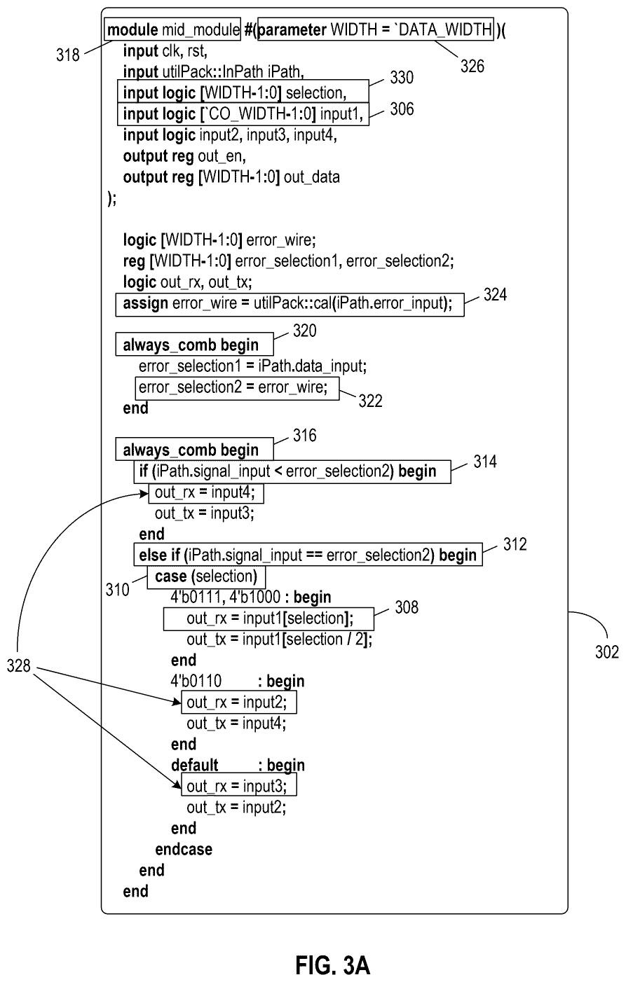

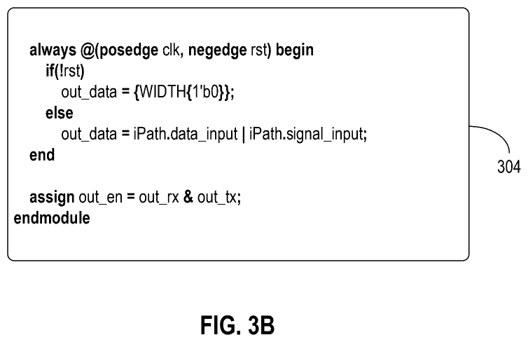

FIGS. 3A-6 illustrate HDL code in accordance with some embodiments described herein.

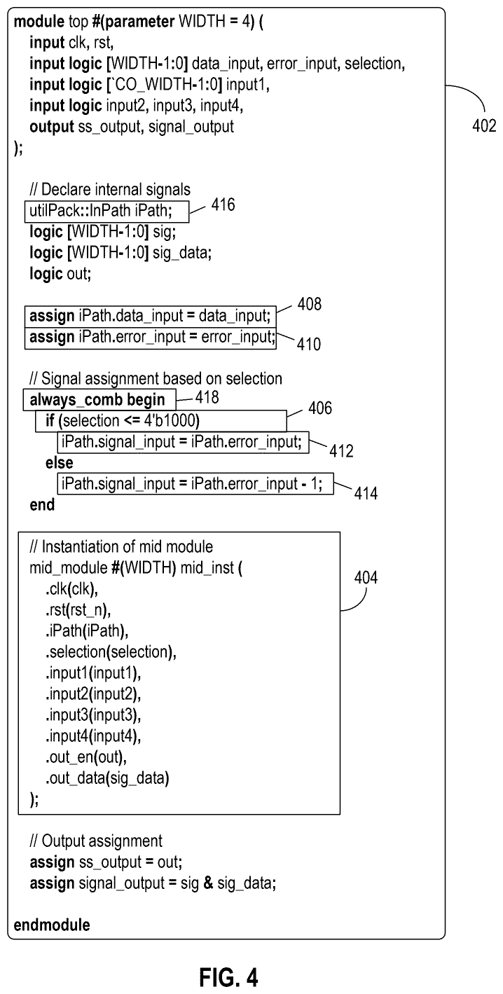

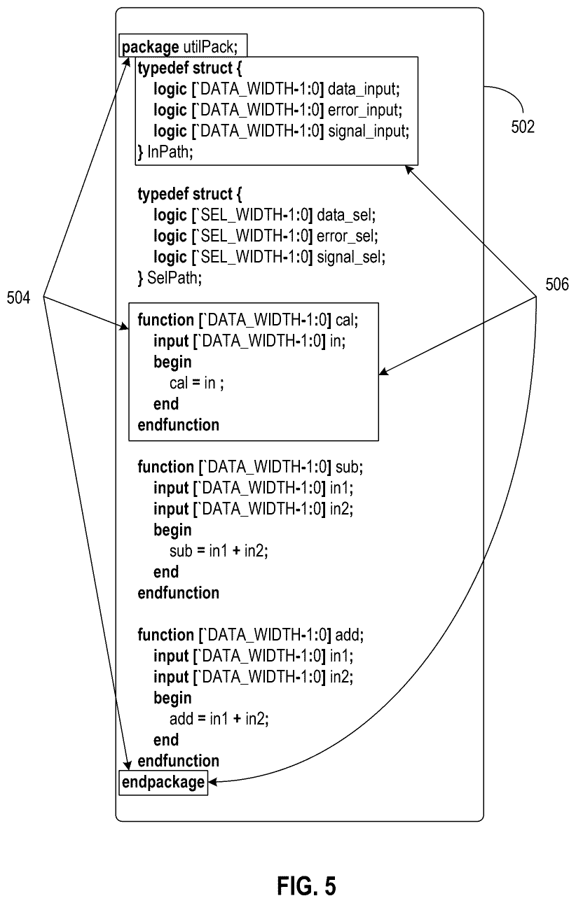

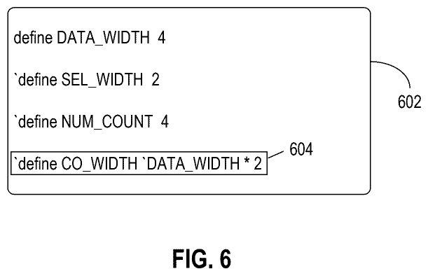

Lines 302 and 304 in FIGS. 3A-3B may define the “mid_module” module in an IC design, lines 402 in FIG. 4 may define a “top” module in the IC design, lines 502 in FIG. 5 may define the “utilPack” package, and lines 602 in FIG. 6 may define constants. The HDL code shown in FIGS. 3A-6 may be stored across multiple HDL files, and objects defined in one HDL file may be used in other HDL files. For example, the “mid_module” defined in FIGS. 3A-3B may be stored in a first HDL file, and the “top” module defined in FIG. 4 may be stored in a second HDL file. It is noted that lines 404 in FIG. 4 which is stored in the second HDL file instantiates the “mid module” module which is defined in FIGS. 3A-3B and stored in the first HDL file.

An index range violation is a type of static violation which may be identified during static verification 232. For example, it may be determined that the variable “selection” in line 308 in FIG. 3A may have a value that is outside the range of index values allowed for array “input1.” Specifically, array “input1” is defined in line 306 with a width of “CO_WIDTH-1,” where the constant “CO_WIDTH” is defined in line 604 in FIG. 6. The index of array “input1” has a range from 0 to 7. However, in line 406 in FIG. 4, the “selection” variable can have the value 8 (i.e., 4′b1000), which may be used in lines 404 to instantiate “mid module.” Thus, the allowable index range (0 to 7) in line 308 in FIG. 3A may be violated when “mid_module” is instantiated with a “selection” value of 8 in lines 404 in FIG. 4.

Providing the entire code base (e.g., all the HDL code in FIGS. 3A-6) to an LLM-based code modifier (e.g., LLM-based code modifier 108) may violate the token limit of the LLM-based code modifier and/or cause the LLM-based code modifier to generate an incorrect fix (e.g., the fix recommended by the LLM-based code modifier may not resolve the index range violation and/or may create new static violations). Some embodiments described herein may generate an HDL slice based on the HDL code shown in FIGS. 3A-6 and provide the HDL slice as part of a prompt to an LLM-based code modifier (e.g., LLM-based code modifier 108).

Specifically, in FIG. 2, violation parser 204 may parse static violations 202 and store the parsed static violations in static violation database 206. Each static violation in static violations 202 may include multiple pieces of information which may include, but are not limited to, a type of static violation, a textual description of the static violation, and a location in the HDL code base where the static violation was identified. Examples of types of static violations include, but are not limited to, an index range violation, a constant value violation in which a variable which is not supposed to have a constant value has a constant value, and a read-write race violation in which a memory address is written to and read from at the same clock edge. Violation parser 204 may identify the type of static violation, the textual description of the static violation, and the location in the HDL code base (e.g., the HDL file, the line number, the module, and the location of the module in the module hierarchy) associated with a static violation. The different pieces of information in the static violation may be stored and associated with each other in the static violation database 206. In some embodiments described herein, the static violation may be specified in extensible Markup Language (XML) format.

HDL code 234 may be parsed by HDL code parser 208 to generate a digital representation of the IC design 210. The term “digital representation” may refer to a representation of the IC design created in a memory of an EDA system. Examples of digital representations include, but are not limited to, a register transfer level (RTL) object model and a netlist object model. The digital representation of the IC design 210 may be analyzed for connectivity and semantic information 212, and the results of the analysis may be stored in connectivity and semantic information database 214. Connectivity information may specify how modules or components in the IC design are connected to each together, which may determine the flow of data or control signals through the IC design. Semantic information may refer to the arrangement of HDL constructs relative to each other, and it may specify the behavior of a portion of the IC design. Examples of HDL constructs which may specify behavior of the IC design include, but are not limited to, modules, instances, variables, loops, and conditional blocks.

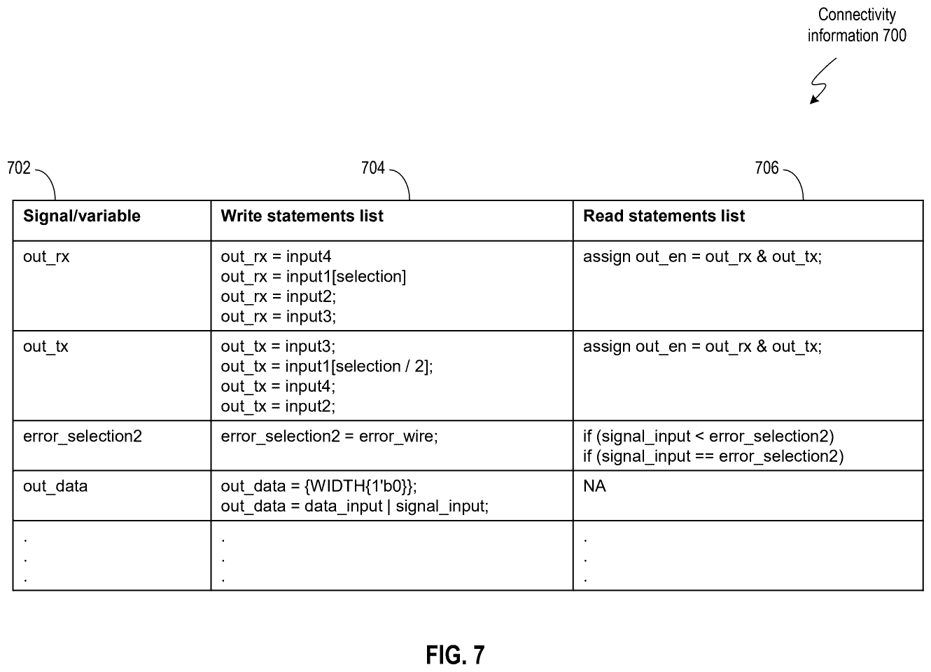

FIG. 7 illustrates connectivity information in an IC design in accordance with some embodiments described herein.

Connectivity information 700 may be represented as a table with a set of rows and columns. The columns may include, but are not limited to, a signal/variable column 702, a write statements list column 704, and a read statements list column 706. The signal/variable column 702 may include a signal or variable name in each row. Specifically, the digital representation of the IC design 210 may be analyzed to identify the signals or variables, and a row in connectivity and semantic database 700 may be created for each identified signal or variable.

For example, connectivity information 700 includes a row for signals/variable “out_rx” which is in the HDL code shown in FIGS. 3A-3B. For each identified signal/variable, the write statements list column 704 may include lines which write, assign, or modify a value to the signal/variable. For example, the line “out_rx =input4” writes or assigns a value to variable “out_rx” and is included in the write statements list column 704 corresponding to the “out_rx” row. For each identified signal/variable, the read statements list column 706 may include lines which read or use the value of the signal/variable, but do not write or modify the value of the signal/variable. For example, the line “assign out_en=out_rx & out_tx” is included in the read statements list column 706 corresponding to the “out_rx” row because the line reads or uses the value of variable “out_rx” but does not modify the value of the variable “out_rx.”

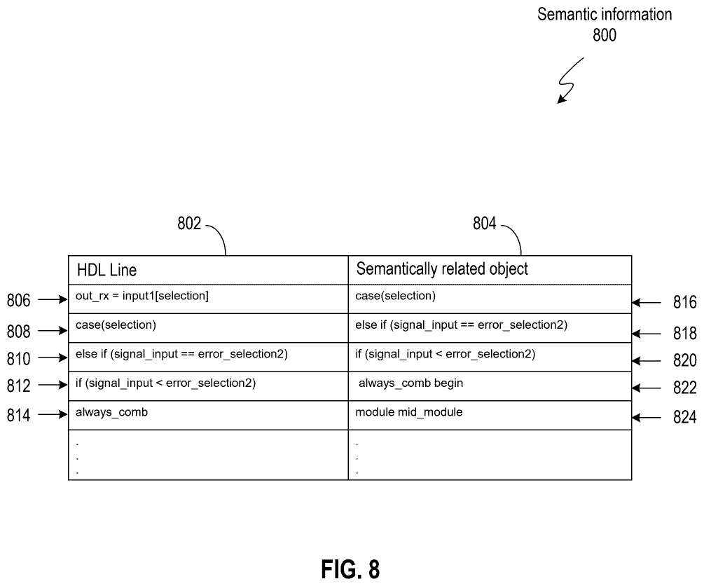

FIG. 8 illustrates semantic information in an IC design in accordance with some embodiments described herein.

In this disclosure, the term “construct” and “object” may be used interchangeably and may refer to an entity in a digital representation of an IC design. Semantic information 800 may be represented as a table with a set of rows and columns. The columns may include, but are not limited to, an HDL line column 802 and a semantically related object column 804. Each row may represent a semantic relationship in the HDL code. Specifically, in a row, column 802 may include an object in the digital representation of the IC design, and column 804 may include a semantically related object.

As explained above, line 308 in FIG. 3A may correspond to an index range violation. Thus, line 308 is shown in cell 806. Line 308 is semantically placed within a “case” construct shown in line 310 in FIG. 3A. Thus, cell 816 includes line 310 in FIG. 3A which is semantically related to line 308. Cells 808 and 818 correspond to line 310 and the semantically related line 312, respectively. Cells 810 and 820 correspond to line 312 and the semantically related line 314, respectively. Cells 812 and 822 correspond to line 314 and the semantically related line 316, respectively. Cells 814 and 824 correspond to line 316 and the semantically related line 318, respectively. A first object may be semantically related to a second object if the second object determines whether the first object is executed and/or the first object is within the context of the second object. For example, the “case” construct in line 310 (e.g., the second object) determines whether line 308 is executed (e.g., the first object). Thus, line 308 may be semantically related to line 310. Line 316 (“always_comb”) is within the context of line 318 (“module mid_module”). Thus, line 316 may be semantically related to line 318.

In FIG. 2, connectivity information 700 and semantic information 800 may be stored in connectivity and semantic information database 214. The static violation database 206, the digital representation of the IC design 210, and the connectivity and semantic information database 214 may be used to identify relevant lines (at 216) for a given static violation.

For example, static violation 236 may be selected from static violation database 206. The HDL statement which caused static violation 236 may be located (at 218). A recursive or iterative process may be used to identify related HDL constructs (at 220) and obtain instance constructs in the parent module (at 222). HDL slicer parameters 224 may be used to adjust the recursive or iterative process. Once the recursive or iterative process terminates, the selected constructs may be used to generate an HDL slice (at 226) based on the lexical representation of the HDL code 228 (which may be generated by HDL code parser 208). The resulting HDL slice 230 may then be provided as part of a prompt to an LLM-based code modifier (e.g., LLM-based code modifier 108).

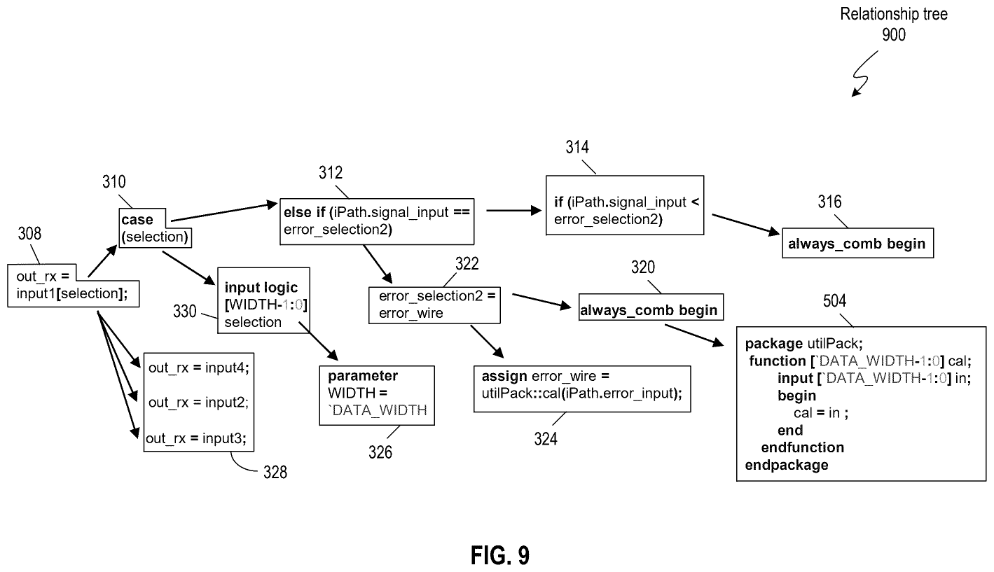

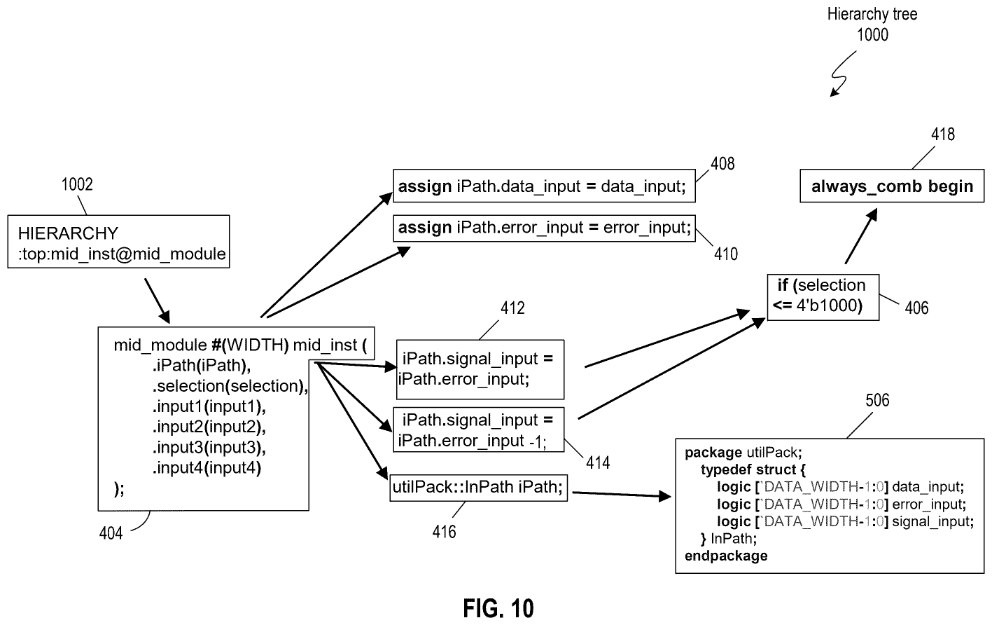

FIGS. 9-10 illustrates identifying related HDL constructs and obtaining instance constructs in the parent module in accordance with some embodiments described herein. In FIGS. 9-10, each box encloses one or more lines and an arrow between two boxes represents a relationship between the lines enclosed in the two boxes.

In FIG. 9, relationship tree 900 may be created by recursively or iteratively identifying constructs in the HDL code shown in FIGS. 3A-6 which are related based on the connectivity and semantic information stored in connectivity and semantic information database 214. The recursive or iterative process may start with the object corresponding to line 308 which is where the static violation was identified. Lines 328 may be identified based on the connectivity information stored in connectivity and semantic information database 214. Specifically, lines 328 may be the lines in code 302 in FIG. 3A which assign a value to the variable “out_rx.” It is noted that lines 328 are not from a block of consecutive lines of code and are selected from different parts in the parse tree. Line 310 may be identified based on the semantic information stored in connectivity and semantic information database 214. Specifically, line 312 is semantically related to line 310 as explained above in reference to FIG. 8. This process may be performed recursively or iteratively until no more semantically related lines can be found in the code base. Specifically, lines 314, 316, 320, 322, 324, 326, 330, and 504 may be identified as lines of HDL code which are related to the static violation corresponding to line 308.

In FIG. 10, hierarchy tree 1000 may be created by recursively or iteratively identifying objects in the HDL code shown in FIGS. 3A-6 which represent the module hierarchy of the IC design. Node 1002 in hierarchy tree 1000 represents the top-level hierarchy shown in lines 402. Lines 404 instantiate the “mid_module” module in the top-level hierarchy. Similarly, the hierarchy can be traced to obtain the other lines in hierarchy tree 1000, which include lines 408, 410, 412, 414, 416, 406, 418, and 506.

In other words, an initial HDL construct which caused the static violation may be identified. Dependent or related constructs may be identified using a recursive or iterative process based on the connectivity and semantic database. After identifying the dependent or related constructs, declaration dependencies for the signals, functions, tasks, typedefs, macros, and packages may be identified. Dependencies related to the hierarchy tree may be identified. The instance hierarchy information may be obtained from the violation. The instance construct in the parent module may be identified and dependencies related to port connection expressions in the instance using the connectivity and semantic database may be identified.

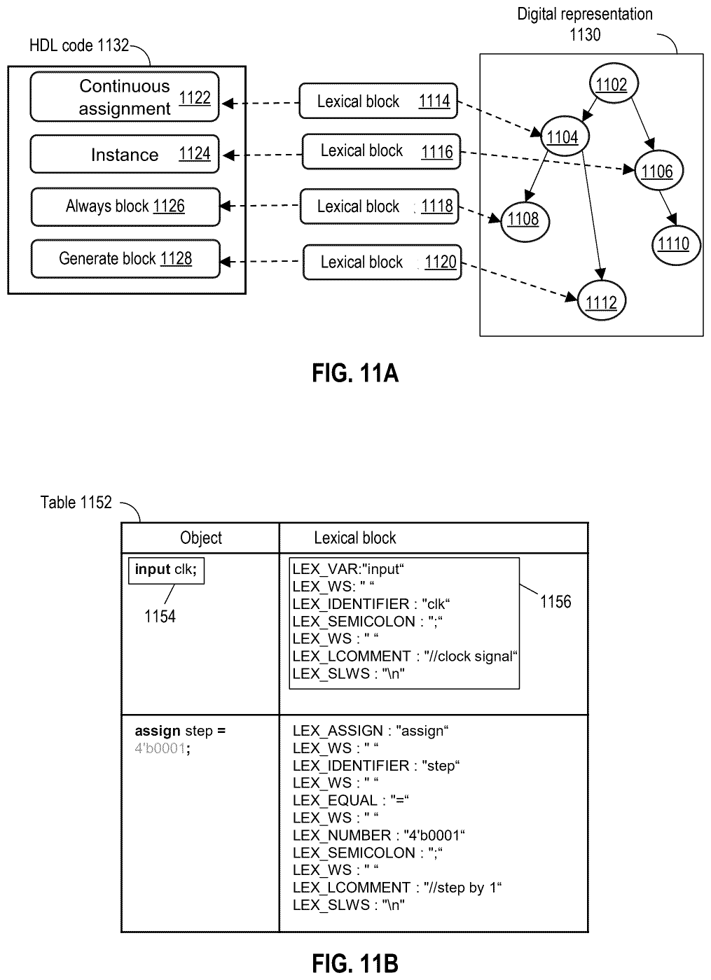

FIGS. 11A-11B illustrate generating an HDL slice based on identifying lines of code corresponding to a set of objects in accordance with some embodiments described herein.

Embodiments described herein may use a lexical object model, which may be a representation of HDL code which is generated when HDL code is complied. A lexical object model may partition or break down the HDL code into basic lexical units which may include, but are not limited to, identifiers (e.g., variable names), keywords (e.g., “if”), and operators (e.g., “+”), punctuation, and special symbols. The lexical units may be grouped into lexical blocks which may correspond to HDL constructs in the digital representation of the IC design. For example, when HDL code 1132 is parsed, it may be partitioned into lexical blocks 1114, 1116, 1118, and 1120, based on the syntax and grammar of the HDL, where each lexical block may correspond to one or more lines of HDL code. For example, lexical block 1114 may correspond to lines for a continuous assignment 1122, lexical block 1116 may correspond to lines which define a module instance 1124, lexical block 1118 may correspond to lines which define an always block 1126, and lexical block 1120 may correspond to lines which define a generate block 1128. The lexical blocks may then be used to create a digital representation 1130 of the IC design, which may include HDL constructs 1102, 1104, 1106, 1108, 1110, and 1112 organized as a parse tree.

Once a set of objects in the digital representation have been identified for a static violation, the corresponding lines in the HDL code may be identified. Specifically, for each object in the set of objects, a corresponding lexical block may be identified, and the lines of HDL code corresponding to the lexical block may be identified. For example, if object 1104 is in the set of selected objects, then lexical block 1114 corresponding to object 1104 may be identified, and the lines for continuous assignment 1122 may be identified. By mapping objects in the digital representation to lexical blocks and mapping the lexical blocks to lines of code in the HDL code base, embodiments described herein can generate an HDL slice which can include preprocessors, parameters, comments, white spaces, and indentations as they are present in the HDL code base.

In FIG. 11B, table 1152 includes two columns. The “Object” column includes a type of object in a digital representation of the IC design, and the “Lexical block” column includes the set of lexical units which map to the object. Specifically, the lexical units may be generated when HDL code is parsed, and a set of lexical units may be mapped to an object in the digital representation of the IC design. For example, the lexical units in lexical block 1156 may be generated by parsing HDL code, and lexical block 1156 may be mapped to object 1154 in the digital representation of the IC design.

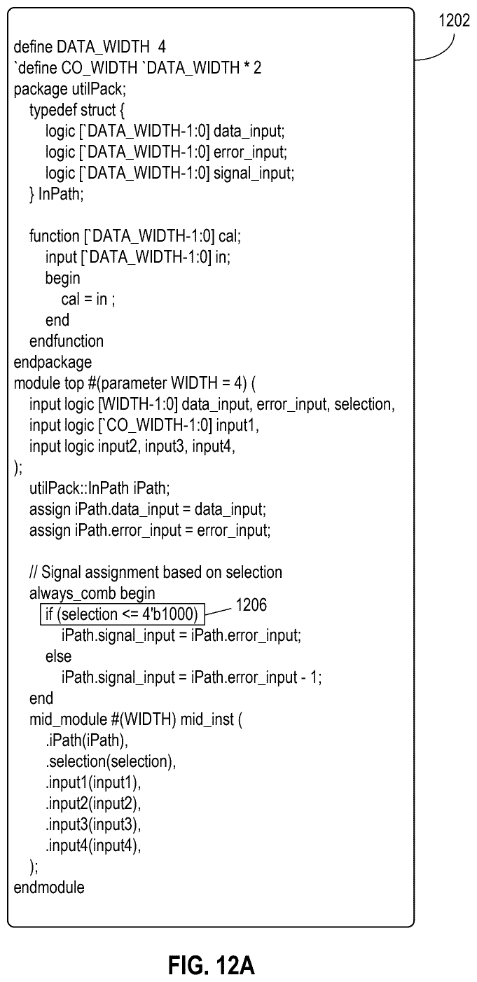

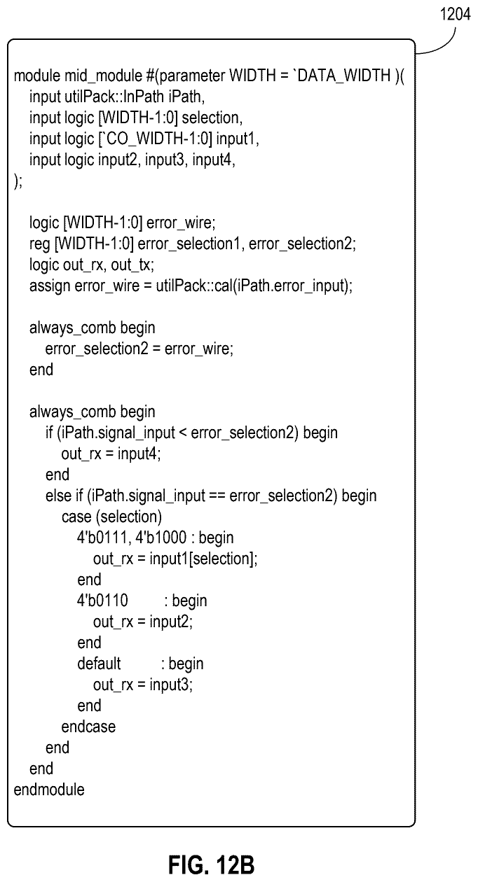

FIGS. 12A-12B illustrate an HDL slice in accordance with some embodiments described herein. Code lines 1202 and 1204 may represent an HDL slice generated based on the HDL code shown in FIGS. 3A-6 and corresponding to the static violation at line 308 (i.e., index range violation) described above in reference to FIG. 3A.

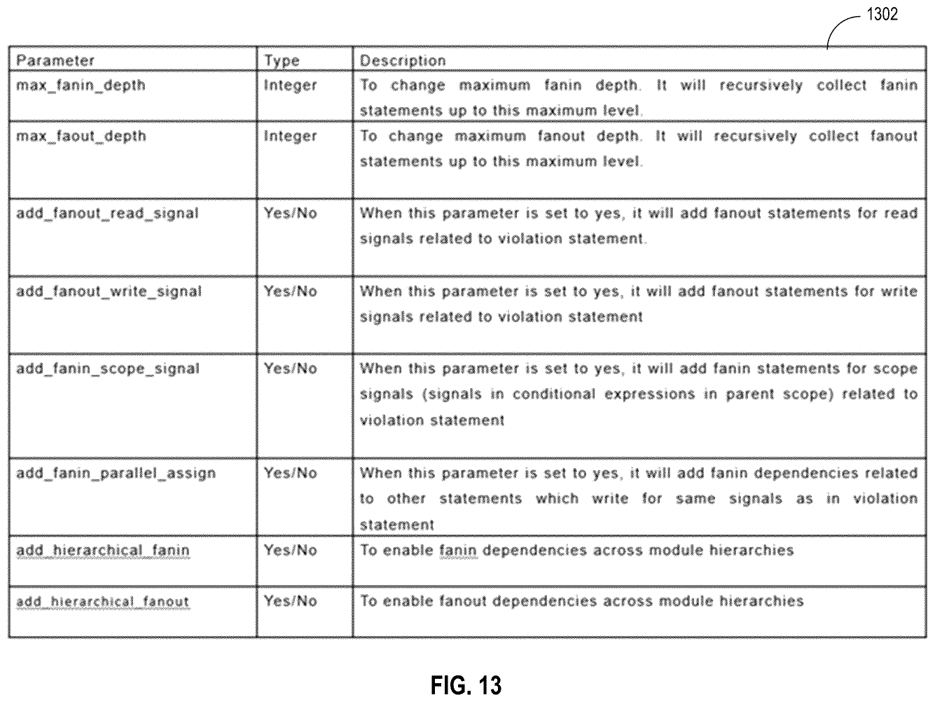

FIG. 13 illustrates parameters to adjust the HDL slice generation process in accordance with some embodiments described herein.

Types of static violations may include, but are not limited to, width mismatch violations, signal usage violations, naming convention violations, port connection violations, structural violations (e.g., index range violations), clock connection violations, and reset connection violations. The HDL slice generation process may be adjusted based on the type of violation. For example, an LLM-based modifier may not need deep dependencies for fixing naming convention violations and width mismatch violations. However, the LLM-based modifier may need deep dependencies for fixing structural violations and clock connection violations.

In some embodiments described herein, each type of static violation may have a corresponding set of parameter values which may be used to adjust the HDL slice generation process. For example, a set of parameter values for each type of static violation may be stored in HDL slicer parameters 224. Table 1302 includes three columns. The column “Parameter” specifies a parameter which adjusts the behavior of the HDL slice generation process, the column “Type” specifies the type of the parameter, and the column “Description” provides a description of the parameter. For example, the first row in table 1302 states that parameter “max_fanin_depth” is an integer and controls the depth of the recursive process of collecting fanin statements. The term “fanin” refers to objects which are connected to the inputs of a given object. The term “fanout” refers to objects which are connected to the outputs of a given object. In the context of HDL code, if a first variable is assigned a value based on a second variable, then the second variable is a fanin object for the first variable, and the first variable is a fanout object for the second object. For example, in the statement “assign x1=x2,” then x2 is a fanin object for x1, and the x1 is a fanout object for x2.

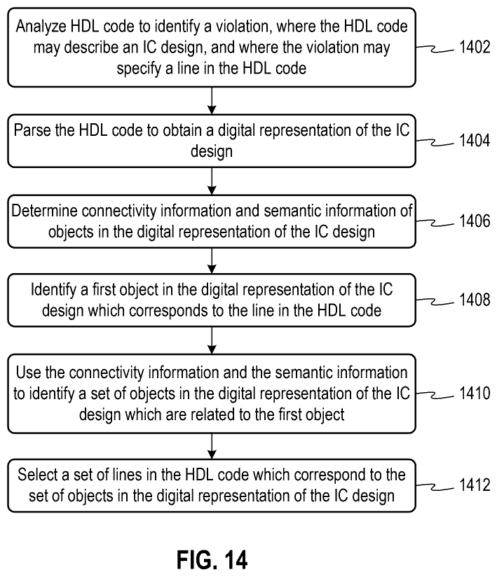

FIG. 14 illustrates a process for generating an HDL slice in in accordance with some embodiments described herein.

HDL code may be analyzed (e.g., by performing static verification on the HDL code) to identify a violation (e.g., a static violation), where the HDL code may describe an IC design, and where the violation may specify a line in the HDL code (at 1402). For example, static verification 232 may be performed on HDL code 234 to identify static violation 202. The index range violation may specify that it was identified in line 308.

The HDL code may be parsed to obtain a digital representation of the IC design (at 1404). For example, HDL code parser 208 may parse HDL code 234 to obtain digital representation of the IC design 210.

Connectivity information and semantic information of objects in the digital representation of the IC design may be determined (at 1406). For example, connectivity information 700 and semantic information 800 may be determined.

A first object in the digital representation of the IC design may be identified which corresponds to the line in the HDL code (at 1408). For example, the object in the digital representation corresponding to line 308 may be identified.

The connectivity information and the semantic information may be used to identify a set of objects in the digital representation of the IC design which are related to the first object (at 1410). For example, relationship tree 900 in FIG. 9 and hierarchy tree 1000 in FIG. 10 include a set of objects in the digital representation of the IC design which are related to the object corresponding to line 308.

A set of lines in the HDL code may be selected which correspond to the set of objects in the digital representation of the IC design (at 1412). For example, code lines 1202 and 1204 are a set of lines in the HDL code which correspond to the set of objects identified in relationship tree 900 in FIG. 9 and hierarchy tree 1000 in FIG. 10. It is noted that code lines 1202 and 1204 are a subset of the code lines shown in FIGS. 3A-6.

In some embodiments described herein, the set of lines in the HDL code may be provided in a prompt to an LLM. A response from the LLM corresponding to the prompt may be received. In some embodiments described herein, a size of the set of lines in the HDL code may be within a token limit of the LLM, and providing the set of lines in the HDL code in the prompt to the LLM may improve an accuracy of the response. The HDL code may be modified based on the response. For example, lines 1202 and 1204 may be the set of lines (i.e., the HDL slice) which is generated for the HDL code shown in FIGS. 3A-6. Lines 1202 and 1204 may be provided as part of a prompt to an LLM. The LLM response may modify line 1206 to the following: “if (selection <4′b1000),” i.e., the LLM response may replace the “<” sign with the “<” sign. This modification to the HDL slice may be made in the original HDL code shown in FIGS. 3A-6, which may fix the violation.

In some embodiments described herein, the violation may be one of a width mismatch violation, a signal usage violation, a naming convention violation, a port connection violation, a structural violation, a clock connection violation, and a reset connection violation.

In some embodiments described herein, identifying the set of objects in the digital representation of the IC design may include iteratively determining object dependencies based on the connectivity information and semantic information up to an iteration limit. In some embodiments described herein, the iteration limit may depend on a type of the static violation. For example, the type of the static violation may be used to select a set of parameter values (e.g., see table 1302), and the set of parameter values may be used to adjust the behavior of the iterative process which determines object dependencies based on the connectivity information and semantic information.

In some embodiments described herein, the connectivity information may associate a first variable in the HDL code with (1) a first set of lines in the HDL code which assign the first variable, and (2) a second set of lines in the HDL code which use the first variable. For example, see connectivity information 700.

In some embodiments described herein, the semantic information may associate a first object with a second object which may be semantically related to the first object. For example, see semantic information 800.

In some embodiments described herein, selecting the set of lines in the HDL code may include identifying a lexical block corresponding to a second object in the set of objects and identifying one or more lines in the HDL code corresponding to the lexical block. For example, see FIGS. 11A-11B.

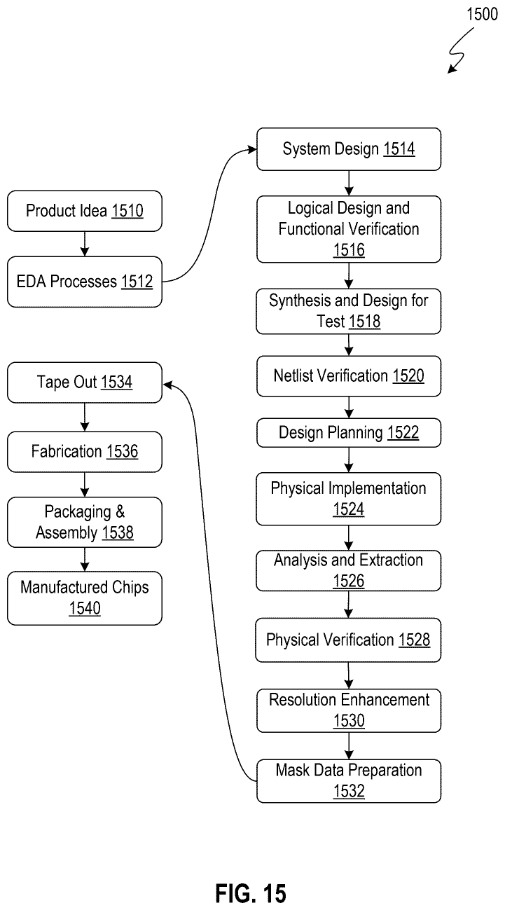

FIG. 15 illustrates an example set of processes 1500 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1510 with information supplied by a designer, information which is transformed to create an article of manufacture that uses a set of EDA processes 1512. When the design is finalized, the design is taped-out 1534, which is when artwork (e.g., geometric patterns) for the integrated circuit is sent to a fabrication facility to manufacture the mask set, which is then used to manufacture the integrated circuit. After tape-out, a semiconductor die is fabricated 1536 and packaging and assembly processes 1538 are performed to produce the finished integrated circuit 1540.

Specifications for a circuit or electronic structure may range from low-level transistor material layouts to high-level description languages. A high-level of representation may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 15. The processes described may be enabled by EDA products (or EDA systems).

During system design 1514, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 1516, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1518, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1520, the netlist is checked for compliance with timing constraints and for correspondence with the HDL code. During design planning 1522, an overall floor plan for the integrated circuit is constructed and analyzed for timing and top-level routing.

During layout or physical implementation 1524, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1526, the circuit function is verified at the layout level, which permits refinement of the layout design. During physical verification 1528, the layout design is checked to ensure that manufacturing constraints are correct, such as DRC constraints, electrical constraints, lithographic constraints, and that circuitry function matches the HDL design specification. During resolution enhancement 1530, the geometry of the layout is transformed to improve how the circuit design is manufactured.

During tape-out, data is created to be used (after lithographic enhancements are applied if appropriate) for production of lithography masks. During mask data preparation 1532, the ‘tape-out’ data is used to produce lithography masks that are used to produce finished integrated circuits.

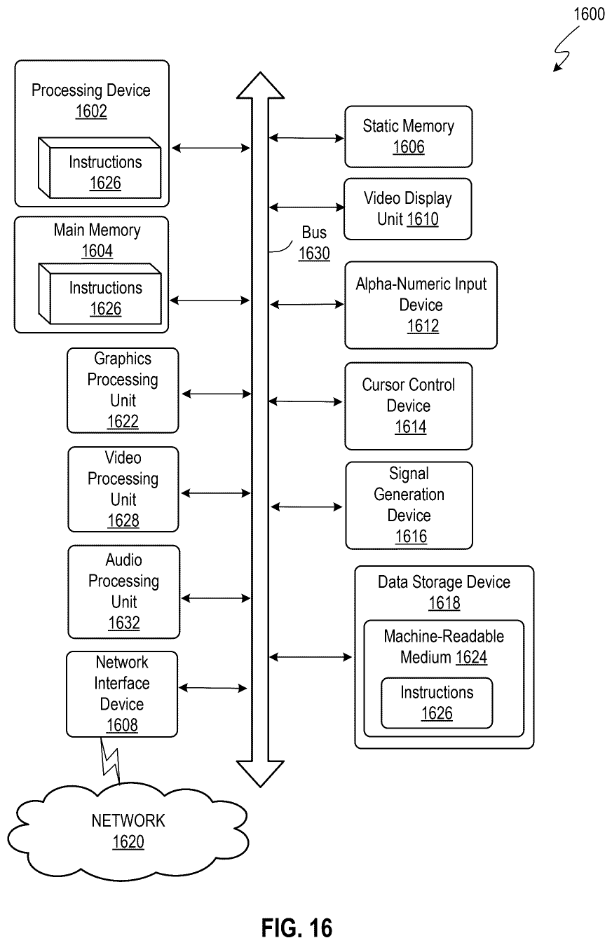

A storage subsystem of a computer system (such as computer system 1600 of FIG. 16) may be used to store the programs and data structures that are used by some or all of the EDA products described herein, and products used for development of cells for the library and for physical and logical design that use the library.

FIG. 16 illustrates an example machine of a computer system 1600 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1600 includes a processing device 1602, a main memory 1604 (e.g., read-only memory (ROM), flash memory, dynamic random access memory (DRAM) such as synchronous DRAM (SDRAM), a static memory 1606 (e.g., flash memory, static random access memory (SRAM), etc.), and a data storage device 1618, which communicate with each other via a bus 1630.

Processing device 1602 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1602 may also be one or more special-purpose processing devices such as an application specific integrated circuit (ASIC), a field programmable gate array (FPGA), a digital signal processor (DSP), network processor, or the like. The processing device 1602 may be configured to execute instructions 1626 for performing the operations and steps described herein.

The computer system 1600 may further include a network interface device 1608 to communicate over the network 1620. The computer system 1600 also may include a video display unit 1610 (e.g., a liquid crystal display (LCD) or a cathode ray tube (CRT)), an alphanumeric input device 1612 (e.g., a keyboard), a cursor control device 1614 (e.g., a mouse), a graphics processing unit 1622, a signal generation device 1616 (e.g., a speaker), graphics processing unit 1622, video processing unit 1628, and audio processing unit 1632.

The data storage device 1618 may include a machine-readable storage medium 1624 (also known as a non-transitory computer-readable medium) on which is stored one or more sets of instructions 1626 or software embodying any one or more of the methodologies or functions described herein. The instructions 1626 may also reside, completely or at least partially, within the main memory 1604 and/or within the processing device 1602 during execution thereof by the computer system 1600, the main memory 1604 and the processing device 1602 also constituting machine-readable storage media.

In some implementations, the instructions 1626 include instructions to implement functionality corresponding to the present disclosure. While the machine-readable storage medium 1624 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1602 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method, comprising:
analyzing hardware description language (HDL) code to identify a violation, wherein the HDL code describes an IC design, and wherein the violation specifies a line in the HDL code;
parsing the HDL code to obtain a digital representation of the IC design;
determining connectivity information and semantic information of objects in the digital representation of the IC design;
identifying a first object in the digital representation of the IC design which corresponds to the line in the HDL code;
using the connectivity information and the semantic information to identify a set of objects in the digital representation of the IC design which are related to the first object; and
selecting, by a processing device, a set of lines in the HDL code which correspond to the set of objects in the digital representation of the IC design.

2. The method of claim 1, further comprising:
providing the set of lines in the HDL code in a prompt to a large language model (LLM);
receiving a response from the LLM which corresponds to the prompt; and
modifying the HDL code based on the response.

3. The method of claim 2, wherein a size of the set of lines in the HDL code is within a token limit of the LLM, and wherein providing the set of lines in the HDL code in the prompt to the LLM improves an accuracy of the response.

4. The method of claim 1, wherein analyzing HDL code includes performing static verification on the HDL code.

5. The method of claim 1, wherein the violation is one of a width mismatch violation, a signal usage violation, a naming convention violation, a port connection violation, a structural violation, a clock connection violation, and a reset connection violation.

6. The method of claim 1, wherein identifying the set of objects in the digital representation of the IC design includes iteratively determining object dependencies based on the connectivity information and the semantic information up to an iteration limit.

7. The method of claim 6, wherein the iteration limit depends on a type of the violation.

8. The method of claim 1, wherein the connectivity information associates a first variable in the HDL code with (1) a first set of lines in the HDL code which assign the first variable, and (2) a second set of lines in the HDL code which use the first variable.

9. The method of claim 1, wherein the semantic information associates a first object with a second object which is semantically related to the first object.

10. The method of claim 1, wherein selecting the set of lines in the HDL code includes identifying a lexical block corresponding to a second object in the set of objects and identifying one or more lines in the HDL code corresponding to the lexical block.

11. A non-transitory computer-readable medium comprising stored instructions, which when executed by a processor, cause the processor to:
analyzing hardware description language (HDL) code to identify a violation, wherein the HDL code describes an IC design, and wherein the violation specifies a line in the HDL code;
parse the HDL code to obtain a digital representation of the IC design;
determine connectivity information and semantic information of objects in the digital representation of the IC design;
identify a first object in the digital representation of the IC design which corresponds to the line in the HDL code;
use the connectivity information and the semantic information to identify a set of objects in the digital representation of the IC design which are related to the first object; and
select a set of lines in the HDL code which correspond to the set of objects in the digital representation of the IC design.

12. The non-transitory computer-readable medium of claim 11, wherein the stored instructions, which when executed by the processor, cause the processor to:
provide the set of lines in the HDL code in a prompt to a large language model (LLM);
receive a response from the LLM which corresponds to the prompt; and
modify the HDL code based on the response.

13. The non-transitory computer-readable medium of claim 12, wherein a size of the set of lines in the HDL code is less than a token limit of the LLM, and wherein providing the set of lines in the HDL code in the prompt improves an accuracy of the response from the LLM.

14. The non-transitory computer-readable medium of claim 11, wherein the violation is one of a width mismatch violation, a signal usage violation, a naming convention violation, a port connection violation, a structural violation, a clock connection violation, and a reset connection violation.

15. The non-transitory computer-readable medium of claim 11, wherein identifying the set of objects in the digital representation of the IC design includes iteratively determining object dependencies based on the connectivity information and the semantic information up to an iteration limit.

16. The non-transitory computer-readable medium of claim 15, wherein the iteration limit depends on a type of the violation.

17. The non-transitory computer-readable medium of claim 11, wherein the connectivity information associates a first variable in the HDL code with (1) a first set of lines in the HDL code which assign the first variable, and (2) a second set of lines in the HDL code which use the first variable.

18. The non-transitory computer-readable medium of claim 11, wherein the semantic information associates a first object with a second object which is semantically related to the first object.

19. The non-transitory computer-readable medium of claim 11, wherein selecting the set of lines in the HDL code includes identifying a lexical block corresponding to a second object in the set of objects and identifying one or more lines in the HDL code corresponding to the lexical block.

20. A system, comprising:
a memory storing instructions; and
a processor, coupled with the memory and to execute the instructions, the instructions when executed causing the processor to:
perform static verification on hardware description language (HDL) code to identify a static violation, wherein the HDL code describes an IC design, and wherein the static violation specifies a line in the HDL code;
parse the HDL code to obtain a digital representation of the IC design;
determine connectivity information and semantic information of objects in the digital representation of the IC design;
identify a first object in the digital representation of the IC design which corresponds to the line in the HDL code;
use the connectivity information and the semantic information to identify a set of objects in the digital representation of the IC design which are related to the first object; and
select a set of lines in the HDL code which correspond to the set of objects in the digital representation of the IC design, wherein selecting the set of lines in the HDL code includes identifying a lexical block corresponding to a second object in the set of objects and identifying one or more lines in the HDL code corresponding to the lexical block.
